(19) United States
(12) Patent Application Publication
(10) Pub. No.: US 2008/0064173 A1
(43) Pub. Date: Mar. 13, 2008

(54) SEMICONDUCTOR DEVICE, CMOS DEVICE AND FABRICATING METHODS OF THE SAME

(75) Inventor: Kuo-Hsin Hung, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNITED MICROELECTRONICS CORP., Hsinchu (TW)

(21) Appl. No.: 11/530,028

(22) Filed: Sep. 8, 2006

(51) Int. Cl. H01L 21/336

(52) U.S. Cl. 438/299

(57) ABSTRACT

A method for fabricating a semiconductor device is described. A transistor is formed on a substrate, including a gate structure on the substrate, a spacer on the sidewall of the gate structure and S/D regions in the substrate beside the gate structure. A liner layer is formed over the substrate conformally covering the transistor, and a portion of the liner layer is removed to form a liner spacer on the spacer of the transistor. A stress layer is formed over the substrate covering the transistor and the liner spacer.

### BACKGROUND OF THE INVENTION

1. Field of Invention

The present invention relates to IC devices and fabricating methods of the same. Particularly, the present invention relates to a semiconductor device, a complementary metal-oxide-semiconductor (CMOS) device and fabricating methods of the same.

2. Description of Related Art

In the evolution of IC devices, higher speed and lower power consumption can be achieved by reducing the device dimension. However, since the reduction in device dimension is currently limited by lithographic resolution and cost, other methods have been developed to increase the operation speed.

One solution for the above issue is the so-called strain technology, which can decrease the resistance of a doped semiconductor layer to increase the driving current. In a method that utilizes a strain effect to increase the device performance, a stress layer is formed covering a transistor to cause in the channel region a strain that changes the Si-cell parameter to increase electron or hole mobility and thereby improve the device performance. Moreover, a selective strain scheme (SSS) can be applied to improve both the electron mobility of NMOS and the hole mobility of PMOS, wherein a tensile stress layer of SiN is formed on NMOS to cause a tensile strain in the channel region and a compressive stress layer of SiN is formed on PMOS to cause a compressive strain in the channel region. The tensile stress layer and the compressive stress layer both can serve as a contact etching stop layer (CESL).

Though the SSS can improve electron mobility and hole mobility at the same time, there are still some issues to be solved. For example, the spacer of a transistor is easily damaged in the over-etching for completely removing the exposed stress layer in the contact opening etching process, so that the device reliability is lowered and the driving current is changed lowering the device performance uniformity. Though a liner layer formed all over a transistor prior to the stress layer can protect the spacer from damage, the driving current (Iₒₙ) gain of a PMOS transistor obtained with the stress layer is much offset due to such a liner layer.

### SUMMARY OF THE INVENTION

In view of the foregoing, this invention provides a method for fabricating a semiconductor device, which can prevent the spacer from being damaged to improve the device reliability and performance uniformity without lowering the driving current gain of the device.

This invention also provides a semiconductor device, which may be fabricated with the above method.

This invention further provides a method for fabricating a CMOS device, which is based on the above method for fabricating a semiconductor device of this invention.

This invention also provides a CMOS device, which may be fabricated with the above method.

The method for fabricating a semiconductor device of this invention is described as follows. A transistor is formed on a substrate, including a gate structure on the substrate, a spacer on the sidewall of the gate structure and source/drain (S/D) regions in the substrate beside the gate structure. A liner layer is formed conformally covering the transistor, and a portion thereof is removed to form a liner spacer on the spacer of the transistor. A stress layer is then formed covering the transistor and the liner spacer.

In some embodiments, the liner spacer may include silicon oxynitride (SiON), silicon oxide (SiO), silicon carbide (SiC) or silicon oxycarbide (SiOC). The step of removing a portion of the liner layer may include an etching process, which may be a wet etching process, a dry etching process or a vapor etching process.

In addition, the stress layer may include silicon nitride (SiN) or SiO. A step of doping or annealing the stress layer may also be included for adjusting the stress of the stress layer. When the transistor is a PMOS (or NMOS) transistor, the stress layer is a compressive (or tensile) stress layer.

The semiconductor device of this invention includes a substrate, a transistor on the substrate, a liner spacer and a stress layer. The transistor includes a gate structure on the substrate, a spacer on the sidewall of the gate structure and S/D regions in the substrate beside the gate structure. The liner spacer is disposed on the spacer of the transistor. The stress layer is disposed on the transistor and the liner spacer.

In some embodiments, the liner spacer may include SiON, SiO, SiC or SiOC. The stress layer may include SiN or SiO. When the transistor is a PMOS (or NMOS) transistor, the stress layer is a compressive (or tensile) stress layer.

The method for fabricating a CMOS device of this invention is described below. A substrate including a first active area and a second active area is provided, and a first transistor of a first conductivity type and a second transistor of a second conductivity type are formed on the first active area and the second active area, respectively. The first transistor includes a gate structure on the substrate, a spacer on the sidewall of the gate structure and S/D regions in the substrate beside the gate structure. The second transistor also includes a gate structure on the substrate, a spacer on the sidewall of the gate structure and S/D regions in the substrate beside the gate structure. A first liner layer is formed covering the first and the second transistors, and a first stress layer and a second liner layer are sequentially formed on the first liner layer. The second liner layer and the first stress layer in the second active area are then removed to expose a surface of the first liner layer, and then a portion of the exposed first liner layer is removed to form a liner spacer on the spacer of the second transistor. A second stress layer is formed conformally covering the second liner layer, the second transistor and the liner spacer, and then the second stress layer in the first active area is removed.

In some embodiments, the liner spacer may include SiON, SiO, SiC or SiOC. The step of removing a portion of the exposed first liner layer to form the liner spacer may include an etching process, which may utilize wet, dry or vapor etching.

Moreover, the first and second stress layers may include SiN or SiO. A doping step or an annealing step may be further done to at least one of the first and the second stress layers to adjust the stress thereof. In addition, when the first transistor is an NMOS transistor and the second transistor a PMOS transistor, the first stress layer is a tensile stress layer and the second stress layer a compressive stress layer.

The CMOS device of this invention includes a substrate, a first transistor, a second transistor, a first liner layer, a liner spacer, a first stress layer, a second liner layer and a second stress layer. The substrate includes a first active area and a second active area. The first transistor is disposed in the first active area, including a gate structure on the substrate, a spacer on the sidewall of the gate structure and S/D regions in the substrate beside the gate structure. The second transistor is disposed in the second active area, also including a gate structure on the substrate, a spacer on the sidewall of the gate structure and S/D regions in the substrate beside the gate structure. The first liner layer is disposed on the first transistor. The liner spacer is disposed on the spacer of the second transistor. The first stress layer is disposed on the first liner layer. The second liner layer is disposed on the first stress layer. The second stress layer is disposed on the second transistor and the liner spacer.

In some embodiments, the liner spacer may include SiON, SiO, SiC or SiOC. The first and second stress layers may include SiN or SiO. When the first transistor is an NMOS transistor and the second transistor a PMOS transistor, the first stress layer is a tensile stress layer and the second stress layer a compressive stress layer.

Since a liner spacer is formed on the spacer of the transistor, the spacer of the transistor is protected from damages so that the device reliability and the performance uniformity are improved. Meanwhile, since this invention forms a liner spacer on the spacer of the transistor rather than a liner layer over the whole transistor, the Iₒₙ gain of a PMOS transistor obtained with the stress layer is not lowered by the liner protection.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A-1D illustrate, in a cross-sectional view, a process flow of fabricating a semiconductor device according to an embodiment of this invention.

FIG. 2 shows the on-current (Iₒₙ) gains of PMOS and NMOS transistors under different conditions.

FIGS. 3A-3G illustrate, in a cross-sectional view, a process flow of fabricating a CMOS device according to another embodiment of this invention.

### DESCRIPTION OF EMBODIMENTS

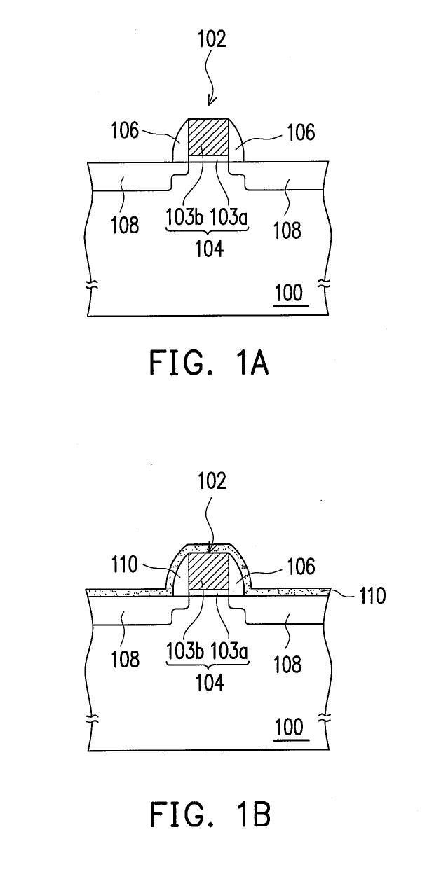

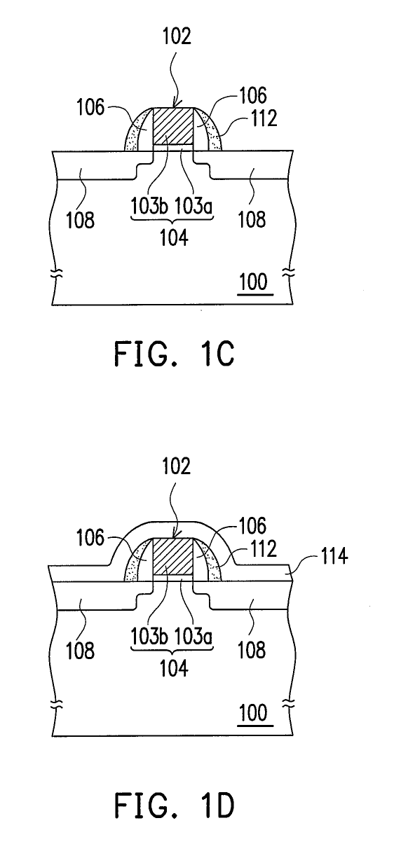

FIGS. 1A-1D illustrate, in a cross-sectional view, a process flow of fabricating a semiconductor device according to an embodiment of this invention.

Referring to FIG. 1A, a substrate 100 is provided, which is possibly a bulk-Si substrate or a semiconductor-on-insulator (SOI) substrate that includes a base substrate, an insulator and a semiconductor layer from bottom to top,. The base substrate may include silicon, the insulator may include SiO, and the semiconductor layer may include Si, epi-Si, Ge, SiGe or C-doped silicon (Si—C).

A transistor 102 is then formed on the substrate 100, possibly with the following steps. A layer of a dielectric material like SiO, SiN or SiON and a layer of a conductor like doped poly-Si are formed in sequence and then patterned into a gate 103b and gate dielectric 103a. The gate dielectric 103a may alternatively include a high-k material like Al₂O₃, Y₂O₃, ZrSiₓO_{y}, HfSiₓO_{y}, La₂O₃, ZrO₂, HfO₂, Ta₂O₅, Pr₂O₃ or TiO₂.

An ion implantation is then conducted to form S/D extensions in the substrate 100 beside the gate structure 104. A spacer 106 is then formed on the sidewall of the gate structure 104, including SiON, SiO, SiC, SiOC or other suitable material. The spacer 106 may be formed by forming a conformal insulating layer over the substrate 100 and then removing a portion of the same through anisotropic etching.

Another ion implantation is then conducted to form heavily doped S/D regions 108 in the substrate 100 beside the spacer 106. In some embodiment, a doped epitaxial layer of Si, SiGe or Si—C may be further formed on the S/D regions 108 to constitute raised S/D structures. In alternative embodiments, each S/D region includes a doped epitaxial layer 108 embedded in the substrate 100 beside the spacer 106. When the transistor 102 is a PMOS transistor, the epitaxial layer may include SiGe; when the transistor 102 is an NMOS transistor, the epitaxial layer may include Si—C. Such S/D regions may be formed by removing a portion of the substrate 100 beside the spacer 106 to form trenches and then growing an epitaxial layer therein with in-situ doping.

In an embodiment, the channel layer between the S/D regions 108 may include a material selected from the group consisting of Si, epi-Si, Ge, SiGe and Si—C.

In some embodiments, a salicide layer (not shown) may be further formed on the top of the gate structure 104 and the S/D regions 108 to reduce the electrical resistance. The salicide includes a silicide of at least one refractory metal selected from Ni, W, Co, Ti, Mo and Pt.

Referring to FIG. 1B, a liner layer 110 is formed over the substrate 100 covering the transistor 102 conformally. The liner layer 110 possibly includes SiON, SiO, SiC, SiOC or other suitable material, and may be formed through CVD or the like.

Referring to FIG. 1C, a portion of the liner layer 110 is removed to form a liner spacer 112 on the spacer 106 of the transistor 102. The removal step may include an etching process, which can be a wet etching process, a dry etching process or a vapor etching process. The wet etching process may utilize phosphoric acid, the dry etching may be plasma etching, and the vapor source used in the vapor etching may be nitric acid, ozone, H₂O₂, HClO, HClO₃, nitrous acid, O₂, H₂SO₄, Cl₂, Br₂, HF or HCl.

Referring to FIG. 1D, a stress layer 114 is then formed over the substrate 100 covering the transistor 102 and the liner spacer 112. The stress layer 114 may include SiN or SiO, and may be formed through LPCVD. A doping step or an annealing step may be further done to the stress layer 114 to decrease or increase the stress thereof. The stress layer 114 is a compressive stress layer when the transistor 102 is a PMOS transistor, or is a tensile stress layer when the transistor 102 is an NMOS transistor.

Since a liner spacer is formed on the spacer of the transistor, the latter is not easily damaged so that the device reliability and performance uniformity are improved.

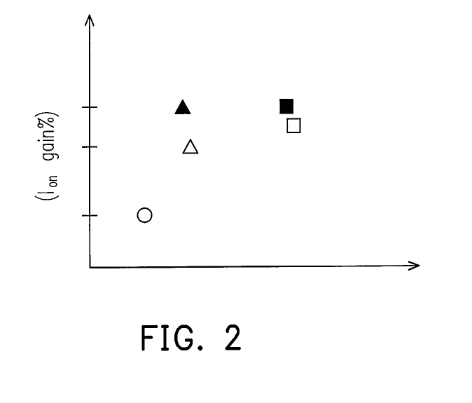

It is particularly noted that in the prior art, forming a liner layer over the whole transistor prior to the stress layer does not change the Iₒₙ gain of NMOS but decreases the Iₒₙ gain of PMOS. FIG. 2 shows the Iₒₙ gains of PMOS and NMOS transistors under different conditions. The symbols “∘”, “▴”, “Δ”, “▪”, and “□” respectively represent a PMOS/NMOS with no stress layer thereon, a PMOS with a stress SiN layer thereon, a PMOS with a whole liner layer and a stress SiN layer thereon, an NMOS with a stress SiN layer thereon, and an NMOS with a whole liner layer and a stress SiN layer thereon. It is clearly shown in FIG. 2 that forming a liner layer covering the whole of a PMOS decreases the Iₒₙ gain thereof. However, since this invention forms a liner spacer that is only on the spacer of the transistor, the Iₒₙ gain of a PMOS transistor is not lowered as the spacer thereof gets protected.

The structure of a semiconductor device in this embodiment is described below in reference of FIG. 1D. The device includes a substrate 100, a transistor 102, a liner spacer 112 and a stress layer 114. The transistor 102 includes a gate structure 104 on the substrate 100, a spacer 106 on the sidewall of the gate structure 104 and S/D regions 108 in the substrate 100 beside the gate structure 104. The liner spacer 112 is disposed on the spacer 106 of the transistor 102, possibly including SiON, SiO, SiC or SiOC. A stress layer 114 is disposed on the transsitor 102 and the liner spacer 112, possibly including SIN or SiO. When the transistor 102 is a PMOS (or NMOS) transistor, the stress layer 114 is a compressive (or tensile) stress layer.

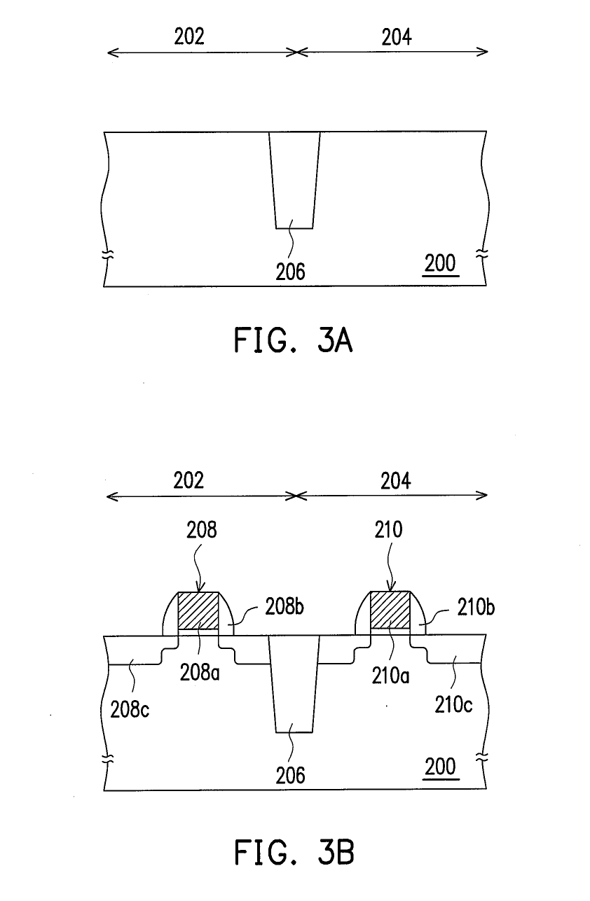

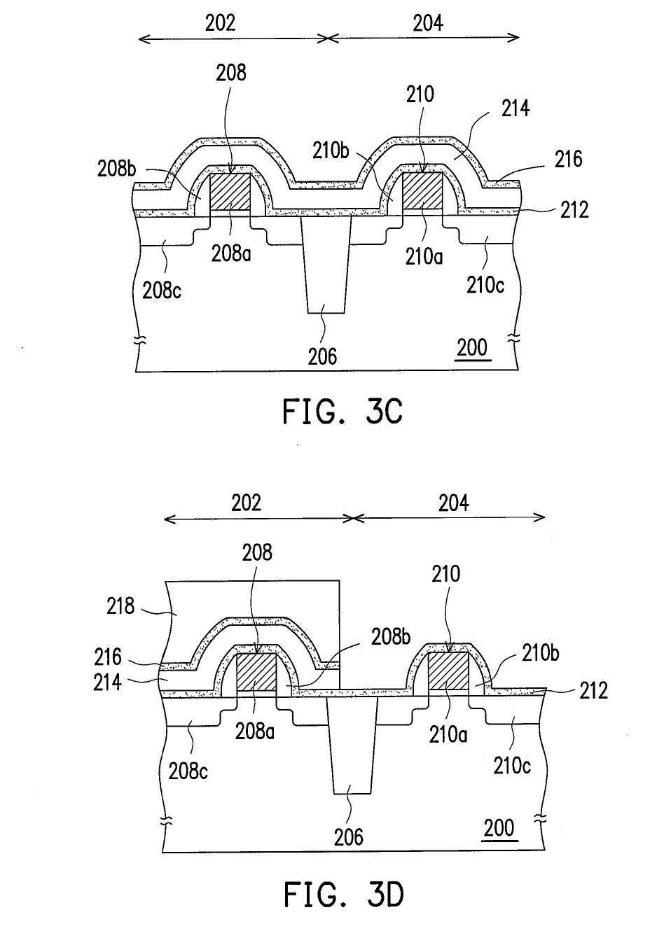

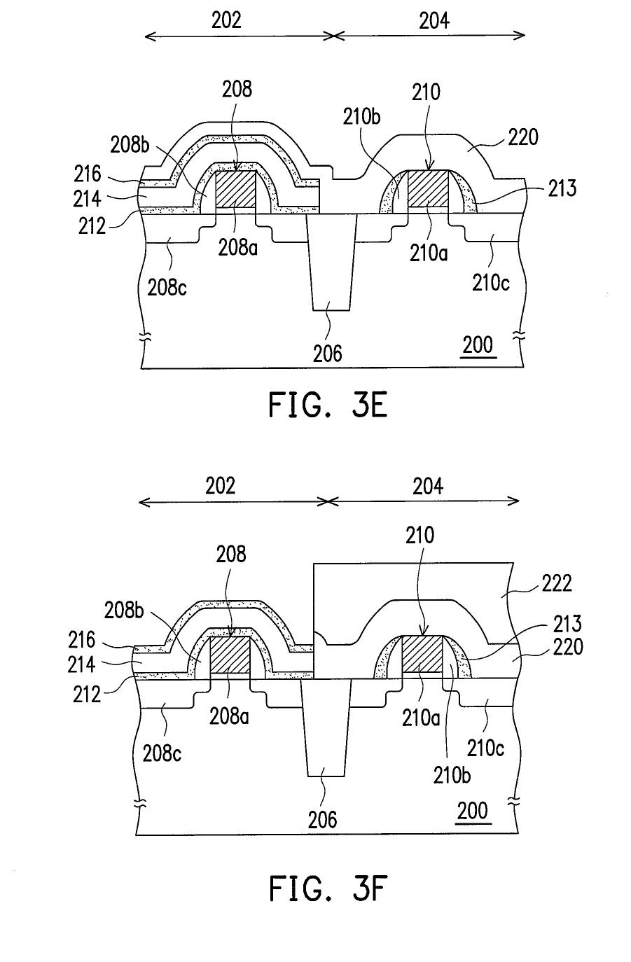

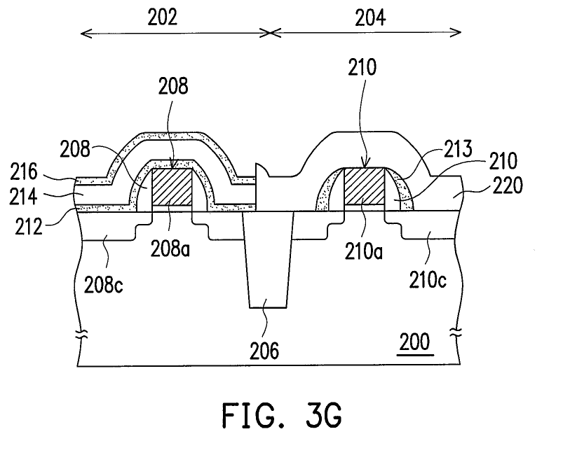

FIGS. 3A-3G illustrate, in a cross-sectional view, a process flow of fabricating a CMOS device according to another embodiment of this invention.

Referring to FIG. 3A, a substrate 200 like a bulk-Si substrate or an SOI substrate is provided. The structure of the SOI substrate may be the same as mentioned above. The substrate 200 includes a first active area 202 and a second active area 204, which two are separated by an isolation structure 206 that may be a shallow trench isolation (STI) structure or other suitable isolation structure.

Referring to FIG. 3B, a first transistor 208 of a first conductivity type and a second transistor 210 of a second conductivity type are formed on the first active area 202 and the second active area 204, respectively. The first transistor 208 includes a gate structure 208a on the substrate 200, a spacer 208b on the sidewall of the gate structure 208a and S/D regions 208c in the substrate 200 beside the gate structure 208a. The second transistor 210 includes a gate structure 210a on the substrate 200, a spacer 210b on the sidewall of the gate structure 210a and S/D regions 210c in the substrate 200 beside the gate structure 210a. Possible forming methods of the transistors 208 and 210 and possible materials of the parts thereof are similar to those mentioned above.

In some embodiments, a salicide layer (not shown) may be formed on the gate structure 208a and S/D regions 208c of the first transistor 208 and on the gate structure 210a and the S/D regions 210c of the second transistor 210 to reduce the resistance of the CMOS device. The material of the salicide layer may be the same as above.

Referring to FIG. 3C, a first liner layer 212 is formed over the substrate 200 conformally covering the first transistor 208, the second transistor 210 and the isolation structure 206. The first liner layer 212 may include SiON, SiO, SiC, SiOC or other suitable material, and may be formed through CVD or other suitable method. A first stress layer 214 is then formed on the first liner layer 212. The first stress layer 214 may include SiN possibly formed through LPCVD, or SiO. In some embodiments, a doping step or an annealing step may be further done to the first stress layer 214 to adjust the stress thereof. A second liner layer 216 is then formed on the first stress layer 214, possibly including SiON, SiO, SiC, SiOC or other suitable material and possibly formed through CVD or other suitable method.

It is noted that when the first transistor 208 is an NMOS transistor and the second transistor 210 a PMOS transistor, the first stress layer 214 is a tensile stress layer and the second stress layer 220 a compressive stress layer.

Referring to FIG. 3D, a photoresist layer 218 is formed on the second liner layer 216 in the first active area 202, and is then used as a mask to etch away the second liner layer 216 and the first stress layer 214 in the second active area 204 to expose a surface of the first line layer 212 in the second active area 204.

Referring to FIG. 3E, after the photoresist layer 218 is removed, a portion of the first liner layer 212 exposed in the second active area 204 is removed to form a liner spacer 213 on the spacer 210b of the second transistor 210. The removal may be done through an etching process, which may be a wet etching process, a dry etching process or a vapor etching process as described above.

Then, a second stress layer 220 is formed over the substrate 200 conformally covering the second liner layer 216, the second transistor 210 and the liner spacer 213. The second stress layer 220 may include SiN possibly formed through LPCVD, or SiO. In some embodiments, a doping step or an annealing step may be further done to the second stress layer 220 to adjust the stress thereof.

Referring to FIG. 3F, a photoresist layer 222 is formed on the second stress layer 220 in the second active area 204, and is then used as a mask to etch away the second stress layer 220 in the first active area 202 to expose a surface of the second liner layer 216 in the first active area 202.

Referring to FIG. 3G, the photoresist layer 222 is then removed. A subsequent interconnect process can be conducted as usual, possibly including the following steps. A dielectric layer is formed over the substrate 200 covering the second stress layer 220 and the second liner layer 216, and then contact openings are formed in the dielectric layer, the first and second stress layers 214 and 220 and the first and second liner layers 212 and 216. A conductive material is then filled into the contact openings to form the contacts of the transistors 208 and 210.

It is particularly noted that in the prior art without any liner formed on the spacer of a transistor, the spacer is easily damaged in the over-etching process for completely removing the stress layer remaining in contact openings. Thus, the spacer is thinned and/or shortened, so that the device reliability is lowered as well as the driving current is changed reducing the device performance uniformity. Though the problems can be avoided by forming a liner layer over the whole transistor prior to the stress layer in the prior art, a liner layer formed all over a PMOS transistor lowers the Iₒₙ gain obtained with the stress layer.

However, since this invention is capable of forming a liner spacer on the spacer of a PMOS transistor, not only the spacer of the transistor is protected but also the on-current (Iₒₙ) gain of the PMOS transistor obtained with the stress layer is not decreased.

The CMOS device structure in this embodiment is described below in reference of FIG. 3G. The CMOS device includes a substrate 200, a first transistor 208 of a first conductivity type, a second transistor 210 of a second conductivity type, a first liner layer 212, a liner spacer 213, a first stress layer 214, a second liner layer 216 and a second stress layer 220. The substrate 200 includes a first active area 202 and a second active layer 204 that are separated by an isolation structure 206. The first/second transistor 208/210 is disposed on the first/second active area 202/204, including a gate structure 208a/210b, a spacer 208b/210b and S/D regions 208c/210c. The first liner layer 212 is disposed on the first transistor 208 in the first active area 202. The liner spacer 213 is disposed on the second transistor 210 in the second active area 204, possibly including SiON, SiO, SiC or SiOC. The first stress layer 214 is disposed on the first liner layer 212, possibly including SiN or SiO. The second liner layer 216 is disposed on the first stress layer 214. The second stress layer 220 is disposed on the second transistor 210 and the liner spacer 213, possibly including SiN or SiO. When the first transistor 208 is an NMOS transistor and the second transistor 210 a PMOS transistor, the first stress layer 214 is a tensile stress layer and the second stress layer 220 a compressive stress layer.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method for fabricating a semiconductor device, comprising:
forming a transistor on a substrate, the transistor including a gate structure on the substrate, a spacer on a sidewall of the gate structure and S/D regions in the substrate beside the gate structure;
forming a liner layer over the substrate, conformally covering the transistor;
removing a portion of the liner layer to form a liner spacer on the spacer of the transistor; and
forming a stress layer over the substrate covering the transistor and the liner spacer.

2. The method of claim 1, wherein the liner spacer comprises SiON, SiO, SiC or SiOC.

3. The method of claim 1, wherein the step of removing a portion of the liner layer to form a liner spacer comprises an etching process.

4. The method of claim 3, wherein the etching process comprises a wet etching process, a dry etching process or a vapor etching process.

5. The method of claim 1, wherein the stress layer comprises SiN or SiO.

6. The method of claim 1, further comprising a step of doping or annealing the stress layer to adjust the stress of the stress layer.

7. The method of claim 1, wherein the transistor is a PMOS transistor, and the stress layer is a compressive stress layer.

8. The method of claim 1, wherein the transistor is an NMOS transistor, and the stress layer is a tensile stress layer.

9. A semiconductor device, comprising:
a substrate;
a transistor on the substrate, including a gate structure on the substrate, a spacer on a sidewall of the gate structure and S/D regions in the substrate beside the gate structure;
a liner spacer on the spacer of the transistor; and
a stress layer on the transistor and the liner spacer.

10. The semiconductor device of claim 9, wherein the liner spacer comprises SiON, SiO, SiC or SiOC.

11. The semiconductor device of claim 9, wherein the stress layer comprises SiN or SiO.

12. The semiconductor device of claim 9, wherein the transistor is a PMOS transistor, and the stress layer is a compressive stress layer.

13. The semiconductor device of claim 9, wherein the transistor is an NMOS transistor, and the stress layer is a tensile stress layer.

14. A method for fabricating a CMOS device, comprising:
providing a substrate including a first active area and a second active area;
forming a first transistor of a first conductivity type and a second transistor of a second conductivity type respectively in the first active area and the second active area, wherein the first transistor includes a gate structure on the substrate, a spacer on a sidewall of the gate structure and S/D regions in the substrate beside the gate structure, and the second transistor includes a gate structure on the substrate, a spacer on a sidewall of the gate structure and S/D regions in the substrate beside the gate structure;
forming a first liner layer over the substrate covering the first and the second transistors;
forming sequentially a first stress layer and a second liner layer on the first liner layer;
removing the second liner layer and the first stress layer in the second active area to expose a surface of the first liner layer in the second active area;
removing a portion of the exposed first liner layer to form a liner spacer on the spacer of the second transistor;
forming a second stress layer over the substrate conformally covering the second liner layer, the second transistor and the liner spacer; and
removing the second stress layer in the first active area.

15. The method of claim 14, wherein the liner spacer comprises SiON, SiO, SiC or SiOC.

16. The method of claim 14, wherein the step of removing a portion of the exposed first liner layer to form a liner spacer comprises an etching process.

17. The method of claim 16, wherein the etching process comprises a wet etching process, a dry etching process or a vapor etching process.

18. The method of claim 14, wherein the first stress layer and the second stress layer comprise SiN or SiO.

19. The method of claim 14, further comprising a doping step or an annealing step done to at least one of the first and the second stress layers to adjust the stress of the same.

20. The method of claim 14, wherein the first transistor is an NMOS transistor, the second transistor is a PMOS transistor, the first stress layer is a tensile stress layer and the second stress layer is a compressive stress layer.

21. A CMOS device, comprising:
a substrate including a first active area and a second active area;
a first transistor of a first conductivity type in the first active area, including a gate structure on the substrate, a spacer on a sidewall of the gate structure and S/D regions in the substrate beside the gate structure;
a second transistor of a second conductivity type in the second active area, including a gate structure on the substrate, a spacer on a sidewall of the gate structure and S/D regions in the substrate beside the gate structure;
a first liner layer on the first transistor;
a liner spacer on the spacer of the second transistor;
a first stress layer on the first liner layer;
a second liner layer on the first stress layer; and
a second stress layer on the second transistor and the liner spacer.

22. The CMOS device of claim 21, wherein the liner spacer comprises SiON, SiO, SiC or SiOC.

23. The CMOS device of claim 21, wherein the first stress layer and the second stress layer comprise SiN or SiO.

24. The CMOS device of claim 21, wherein the first transistor is an NMOS transistor, the second transistor is a PMOS transistor, the first stress layer is a tensile stress layer and the second stress layer is a compressive stress layer.
